(19) United States
(12) Patent Application Publication
(10) Pub. No.: US 2014/0203245 A1
(43) Pub. Date: Jul. 24, 2014

(54) Active Matrix Organic Light Emitting Diode Display Having Variable Optical Path Length for Microcavity

(71) Applicant: APPLE INC., Cupertino, CA (US)

(72) Inventors: Vasudha Gupta, Cupertino, CA (US); Young Bae Park, Cupertino, CA (US); Shih Chang Chang, Cupertino, CA (US)

(73) Assignee: Apple Inc., Cupertino, CA (US)

(21) Appl. No.: 13/749,394

(22) Filed: Jan. 24, 2013

(51) Int. Cl. H01L 51/52; H01L 51/56

(52) U.S. Cl. CPC H01L 51/5203; H01L 51/56
USPC 257/40; 257/59; 438/23

(57) ABSTRACT

An organic light emitting diode display includes an array of pixels on a substrate. Each pixel includes three sub-pixels that emits light of different wavelengths from each other. The display includes thin film transistors (TFTs) for the sub-pixels on the substrate. Each TFT is separated from each other by a first pixel defining layer. The display also includes a first pixel electrode connected to the TFT for each sub-pixel, a tuning layer on the first pixel electrode, where the tuning layer has a thickness for each sub-pixel such that each sub-pixel has a optical-path length different from another sub-pixel. The display further includes an organic light emitting layer disposed over the tuning layer, and a second pixel defining layer covering a first end of the tuning layer and a second end of the tuning layer opposing to the first end of the tuning layer, and exposing the light emitting layer.

### TECHNICAL FIELD

Embodiments described herein generally relate to active matrix organic light emitting diode (AMOLED) displays. More specifically, certain embodiments relate to processes for realizing a variable optical path length for one or more microcavities in an AMOLED display.

### BACKGROUND

Active matrix organic light emitting diode (AMOLED) displays are becoming more mainstream, due to their better contrast ratios when compared to conventional liquid crystal displays (LCDs). AMOLED displays are self-emissive devices, and do not require backlights. AMOLED displays may also provide more vivid colors and a larger color gamut than the conventional LCDs. Further, AMOLED displays can be made more flexible, thinner, and lighter than a typical LCD.

An OLED generally includes an anode, one or more organic layers, and a cathode. A microcavity is formed between the anode and the cathode. The AMOLEDs often use the microcavity to enhance color purity of a display. In the microcavity, an optical path length between the anode and the cathode may be tuned to enhance the aforementioned color purity.

AMOLEDs can either be a bottom emission type or a top emission type. In bottom emission OLEDs, the light is extracted from an anode side. In such embodiments, the anode is generally transparent, while a cathode is generally reflective. The pixel area is shared between the OLED and a backplane driving circuit that includes thin film transistors (TFT), metal routing, capacitors. The driving circuit may contain a few TFTs, for example, three to five TFTs, with few control signals, and one or two capacitors. As a result, the area available for OLED is limited such that an OLED aperture is small.

In a top emission OLED, light is extracted from a cathode side. The cathode is optically transparent, while the anode is reflective. This top emission OLED normally enables a larger OLED aperture than a bottom emission OLED.

### SUMMARY

Embodiments described herein may take the form of AMOLED displays and/or methods for fabricating AMOLED displays. AMOLED displays described herein may have a different optical path length for each sub-pixel emitting light of a different wavelength, such that each sub-pixel has a microcavity tuned for each respective wavelength. The different optical wavelengths are achieved by including a tuning layer between the anode and the cathode. The tuning layer has different thicknesses for each of the sub-pixels. This disclosure also provides methods for achieving different thicknesses of the tuning layer without using extra masking operations or with only one extra masking operation, when compared to conventional fabrication techniques. For example, a shadow mask may be used for depositing the OLED layer. Methods described herein may use the same shadow mask for depositing the tuning layer. This method is much simpler than a conventional process which generally requires four extra masks in order to deposit a second ITO layer having different thicknesses for different sub-pixels.

In one embodiment, an organic light emitting diode display includes a plurality of pixels on a substrate, where each pixel has at least three sub-pixels, and each sub-pixel emits light of different wavelengths from each other. The display also includes thin film transistors (TFTs) for the at least two sub-pixels on the substrate, each of the at least two TFTs being separated from each other by a first pixel defining layer. The display further includes a pixel electrode connected to the TFT for each sub-pixel, and a tuning layer on the first pixel electrode, where the tuning layer has a thickness for each sub-pixel such that each sub-pixel has an optical-path length different from another sub-pixel. The display also includes an organic light emitting layer disposed over the tuning layer; and a second pixel defining layer covering a first end of the tuning layer and a second end of the tuning layer opposing to the first end of the tuning layer, and exposing the light emitting layer. The display further includes a common electrode disposed over the second pixel defining layer and the light emitting layer for the plurality of the pixels and the at least three sub-pixels, where a microcavity is formed between the first pixel electrode and the second pixel electrode for each sub-pixel.

In another embodiment, a method is provided for fabricating a top emission organic light emitting diode (OLED) display having a plurality of pixels, each pixel having at least three sub-pixels. The method includes forming a plurality of first pixel electrodes for the sub-pixels over a thin film transistor (TFT) substrate such that the first pixel electrode for one sub-pixel is separated from another sub-pixel by a first pixel defining layer and disposing an tuning layer over the first pixel electrode by using a shadow mask, the tuning layer having a different thickness for each sub-pixel that emits light of a different wavelength, the shadow mask being different for each sub-pixel. The method also includes depositing a second pixel defining layer over the tuning layer and removing a first portion of the second pixel defining layer such that a middle portion of the tuning layer is exposed and an end portion remains covered by a remaining second portion of the second pixel defining layer. The method further includes disposing a light emitting layer over the middle portion of the tuning layer by using the shadow mask and forming a common electrode over the light emitting layer and the remaining second portion of the second pixel defining layer for the plurality of pixels and the at least three sub-pixels.

In a further embodiment, an organic light emitting diode display includes a plurality of pixels on a substrate, where each pixel includes three sub-pixels, and each sub-pixel emits light of different wavelengths from each other. The display also includes thin film transistors (TFTs) for the sub-pixels on the substrate, each TFT being separated from each other by a first pixel defining layer. The display further includes a pixel electrode connected to the TFT for each sub-pixel, and a tuning layer on the first pixel electrode, where the tuning layer has a thickness for each sub-pixel such that each sub-pixel has an optical-path length different from another sub-pixel. the display also includes an organic light emitting layer disposed over the tuning layer, and a second pixel defining layer covering a first end of the tuning layer and a second end of the tuning layer opposing to the first end of the tuning layer, and exposing the light emitting layer.

Additional embodiments and features are set forth in part in the description that follows, and in part will become apparent to those skilled in the art upon examination of the specification or may be learned by the practice of the embodiments discussed herein. A further understanding of the nature and advantages of certain embodiments may be realized by reference to the remaining portions of the specification and the drawings, which forms a part of this disclosure.

### BRIEF DESCRIPTION OF THE DRAWINGS

FIG. 1A illustrates a perspective view of a sample electronic device in accordance with one embodiment of the present disclosure.

FIG. 1B illustrates a detailed view of the display of FIG. 1A with an array of pixels in accordance with certain embodiments of the present disclosure.

FIG. 1C illustrates a detailed view of the pixel of FIG. 1B showing sub-pixels in accordance with certain embodiments of the present disclosure.

FIG. 2 illustrates a cross-sectional view of a top emission OLED of the sample electronic device of FIG. 1A and taken along line 2-2 of FIG. 1A in accordance with certain embodiments of the present disclosure

FIG. 3 illustrates a detailed cross-sectional view of a portion of the top emission OLED of FIG. 2 in accordance with embodiment of the present disclosure.

FIG. 4A shows a cross-sectional view of a process architecture including anode and indium-tin oxide (ITO) photo patterning for the top emission OLED display of FIG. 2 in a first embodiment of the present disclosure.

FIG. 4B shows a cross-sectional view of a process architecture including pixel defining layer (PDL) deposition and photo patterning for the top emission OLED display following the operation of FIG. 4A.

FIG. 4C shows a cross-sectional view of a process architecture including tuning layer deposition by using a shadow mask for the top emission OLED display following the operation of FIG. 4B.

FIG. 4D shows a cross-sectional view of a process architecture including second pixel defining layer (PDL) deposition for the top emission OLED display following the operation of FIG. 4C.

FIG. 4E shows a cross-sectional view of a process architecture including photo patterning of the second PDL for the top emission OLED display following the operation of FIG. 4D.

FIG. 4F shows a cross-sectional view of a process architecture including light emitting layer deposition and common electrode deposition for the top emission OLED display following the operation of FIG. 4E.

FIG. 5A shows a cross-sectional view of a process architecture including anode and ITO photo patterning for a top emission OLED display in a second embodiment of the present disclosure.

FIG. 5B shows a cross-sectional view of a process architecture including pixel defining layer (PDL) deposition and photo patterning for the top emission OLED display following the operation of FIG. 5A.

FIG. 5C shows a cross-sectional view of a process architecture including tuning layer deposition by using a shadow mask for the top emission OLED display following the operation of FIG. 5B.

FIG. 5D shows a cross-sectional view of a process architecture including second pixel defining layer (PDL) deposition for the top emission OLED display following the operation of FIG. 5C.

FIG. 5E shows a cross-sectional view of a process including photo patterning of the second PDL for the top emission OLED display following the operation of FIG. 5D.

FIG. 5F shows a cross-sectional view of a process architecture including light emitting layer deposition and common electrode deposition for the top emission OLED display following the operation of FIG. 5E.

FIG. 6 illustrates a cross-sectional view of a bottom emission OLED in accordance with certain embodiments of the present disclosure.

### DETAILED DESCRIPTION

The present disclosure may be understood by reference to the following detailed description, taken in conjunction with the drawings as described below. It is noted that, for purposes of illustrative clarity, certain elements in various drawings may not be drawn to scale.

This disclosure discusses AMOLED displays having variable optical path lengths for microcavities corresponding to different sub-pixels, such as red, green and blue sub-pixels. The disclosure also provides methods of fabricating such AMOLED displays.

AMOLED displays may be used in a variety of computing displays and devices, including notebook computers, desktop computers, tablet computing devices, mobile phones (including smart phones), automobile in-cabin displays, on appliances, as televisions, and so on. In AMOLED displays, a thin-film transistor (TFT) is used as a switching element in an active matrix. Typically, display pixels are addressed in rows and columns, which may reduce the connection count from millions for each individual pixel to thousands, when compared to a display having pixels addressed only by rows and/or columns. The column and row wires attach to transistor switches; at least one transistor is present for each pixel. The one-way current passing characteristic of the transistor prevents the charge applied to the pixel from draining between refreshes of the display image.

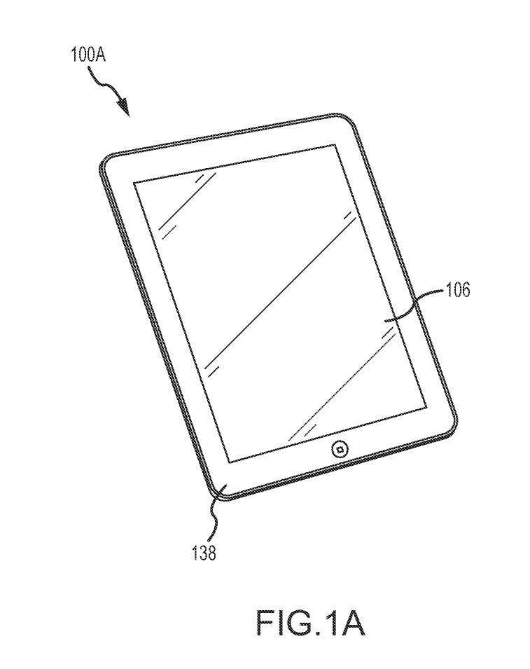

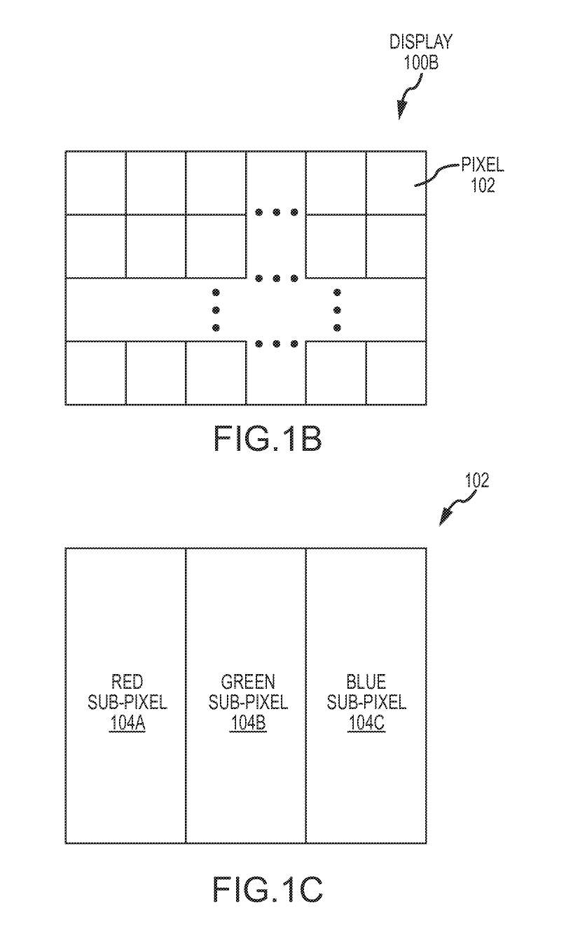

FIG. 1A illustrates a perspective view of a sample electronic device such as a tablet computer in accordance with certain embodiments of the present disclosure. The electronic device includes a touch screen display 100 enclosed by a housing 138. The touch screen display 100 incorporates a cover glass 106 and an AMOLED display behind the cover glass 106, although alternative embodiments may employ an LCD instead of an organic light-emitting display (OLED).

FIG. 1B illustrates a detailed view of the display of FIG. 1A with an array of pixels in accordance with certain embodiments of the present disclosure. As shown, display 100B includes an array of pixels 102. There are a number of rows of pixels and a number of columns of pixels. The dots between the rows and between the columns signify that the number of rows and columns may be arbitrary; that is, the number of rows and columns may vary between embodiments and no fixed number of either is required for any given embodiment or to incorporate the teachings in this document. The number of pixels depends upon the size and resolution of the display. A pixel may be divided into sub-pixels of different colors. FIG. 10 illustrates a detailed view of a sample pixel of FIG. 1B showing a group of sub-pixels 104A, 104B, 104C that make up the pixel, in accordance with certain embodiments of the present disclosure. As shown, pixel 102 may include red sub-pixel 104A, green sub-pixel 104B, and blue sub-pixel 104C. The sub-pixels are arranged to share the pixel area such that each sub-pixel 104A, 104B, or 104C is smaller than the pixel 102. It should be appreciated that the layout of the sub-pixels 104A, 104B, 104C shown in FIG. 10 is but one sample layout; the relative positions and alignments of the sub-pixels may vary between embodiments.

Top emission OLEDs generally have a longer operating life, than do bottom emission OLEDs. The is because top emission OLEDs may have a larger light emission aperture than do bottom emission OLEDs, which may help reduce current density in the OLED. When the current density is high in the OLED, more heat is generated when the OLED emits light, such that a life time of the OLED may be shortened. The current requirement increases with the display panel size. For example, even if the number of pixels per inch (PPI) is not high in a large sized display (e.g., the display may have low resolution, despite its size), the current requirement may still be large because of the larger panel size. A low PPI may be 80 or less, in some embodiments.

AMOLED displays, such as may be used in televisions, computer tablets, and the like, are designed for long usage lives. For example, a lifetime equal or greater than 50,000 hours for the OLED displays may be required. Therefore, employing top emission OLED displays in such products may help increase the OLED aperture, reduce current density through the OLED, and improve the OLED lifetime.

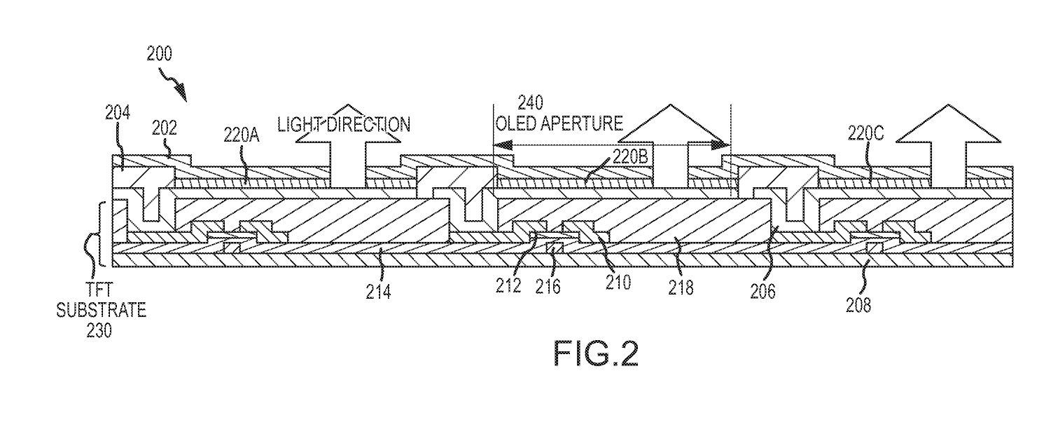

FIG. 2 illustrates a cross-sectional view of a top emission OLED in accordance with certain embodiments of the present disclosure. As shown, top emission OLED display 200 includes a TFT substrate 230, an anode 206, a cathode 202, and an OLED emissive layer (EML) 220 situated between the anode 206 and cathode 202 for a single pixel. The emissive layer 220 has a first sub-pixel region 104A with EML 220A for emitting red light, a second sub-pixel region 104B with EML 220B for emitting green light, and a third sub-pixel region 104C with EML 220C for emitting green light. The sub-pixel regions are defined by a pixel defining layer 204. The PDL layer 204 may be formed of an organic material or an inorganic material. The anode 206 is disposed over a planarization layer 218, which is disposed on top of the TFT substrate 230. The planarization layer 218 may be formed of an organic material.

The TFT substrate 230 includes a substrate 208 on a bottom and three gate metals 216 corresponding to each sub-pixel region 220A, 220B, and 220C on the substrate 208. The TFT substrate 230 also includes a gate insulator 214 disposed over the gate metals 216. The TFT substrate further includes channel 212, source and drain metal 210 patterned on the gate insulator 214. The channel 212 is formed from a semiconductor, which may be either amorphous silicon (a-Si) or metal oxide such as an indium-gallium-zinc oxide (IGZO). As shown, the light emitting from the EMLs 220A, 220B, and 220C comes from the top surface of the display, as shown by the arrow.

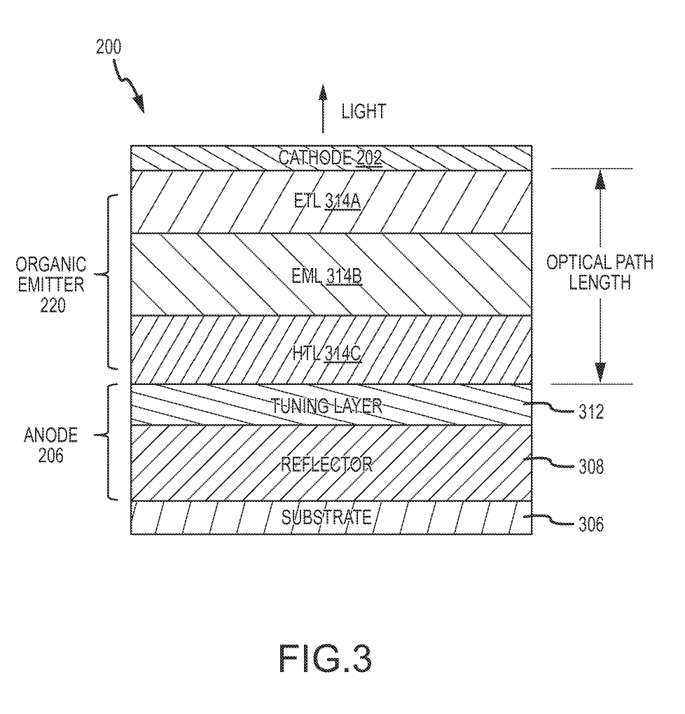

FIG. 3 illustrates a detailed cross-sectional view of a portion of the top emission OLED of FIG. 2 in accordance with certain embodiments of the present disclosure. This detailed view shows more details of the layers between an anode and a cathode, but simplifies the TFT structure and planarization layer 218. The top emission OLED 200 is structured so that a first electrode 206 (anode) is formed from a light-reflecting material and a second electrode 202 (cathode) is formed from a transparent material. An organic, light-emissive layer 220 is positioned between the cathode 202 and anode 206. As shown, the anode 206 includes a light reflector 308 on top of a substrate 306, and a tuning layer 312 deposited over the reflector 308. The substrate 306 is analogous to, and may incorporate, the previously-discussed TFT substrate 230 and/or planarization layer 218.

The cathode 202 generally injects electrons into an electron transport layer (ETL) 314A when a negative potential relative to the anode is applied It should be mentioned that the layers are for illustrative purpose only and not intended to represent actual ratios or relative thicknesses. The cathode 202 generally may be highly transparent or semi-transparent in order to transmit light without significant absorption. The cathode may be formed of a transparent conductive layer, such as indium-tin oxide (ITO) or a thin (about 10 to 20 nm) silver or magnesium-silver film as an electron injection layer. The cathode may also be formed of other transparent materials, including, but not limited to, inorganic compound, such as lithium fluoride (LiF), and the like. Note that the reflectivity of the cathode is small compared to that of Anode.

The organic emitter 220 may include an electron transport layer (ETL) 314A, an emissive layer (EML) 314B, and/or a hole transport layer (HTL) 314C. The ETL 314A delivers electrons injected from the cathode 202 to the emissive layer 314B. The EML 314B emits light corresponding to an electric current provided to the EML and includes an organic compound that functions as the light-emitting material. The EML 314B emits light as a result of recombination of holes and electrons. The EML 314B includes small molecules which may be deposited by evaporation in vacuum, polymer based solution, fluorescent, and phosphorescent, etc. The HTL 314C transports holes to the emissive layer 314B. A hole injection layer may be added to the organic emitter 220 to increase the efficiency of the hole-injection from the anode 206.

The organic emitter 220 serves as a resonance part in a microcavity formed between the anode 206, also called a “pixel electrode,” and the cathode 202, also referred to as a “common electrode.” Each sub-pixel 220A, 220B, 220C includes a microcavity that enhances light emission at a particular wavelength as determined by optical path length of the microcavity. Examples of such microcavity devices are shown in U.S. Pat. Nos. 5,505,710 and 5,554,911.

An optical path length is defined as refractive index multiplied by the thickness for each organic emitter 220 between the anode 206 and the cathode 202. The optical path length between the anode and cathode may be controlled by changing the distance between the anode 206 and cathode 202.

The anode 206 provides the function of injecting holes into the organic layer when a positive potential relative to the cathode is applied. The anode 206 includes a light reflector 308 which may be a reflective metal and a tuning layer on top of the reflective metal helps tune the microcavity. The reflector 308 helps improve efficiency of light emission through the top emission OLED. The reflector 308 may be formed from any suitable material, including silver (Ag), aluminum (AL), gold (Au), and the like, as well as alloys of these, or other metals. In a particular embodiment, silver is used for both the reflector 308 in the anode 206 and the metal layer 302B in the cathode 202, as silver has very high reflectivity, for example, greater than 90% at a wavelength of 550 nm.

The tuning layer 312 may be made of indium tin oxide (ITO). The tuning layer 312 may also be made of other materials such as, indium zinc oxide (IZO), aluminum doped zinc oxide (AZO), or combinations thereof.

The substrate 306 may include various materials that may be opaque, semitransparent or transparent, such as glass, ceramic, metal, plastic, and the like. The substrate 306 may take any suitable form, such as a rigid plate, flexible sheet, or curved surface(s). The substrate 306 may also be an active matrix substrate that includes one or more thin-film transistors, such as TFT substrate 230. It will be appreciated by those skilled in the art that the substrate may also include other circuit elements.

### Photolithography Process

The tuning layer 312 may be deposited using photolithography to create different thicknesses having various optical path lengths. Thus, microcavities corresponding to different wavelengths may be formed for each of the sub-pixels. The present disclosure provides methods to generate a tuning layer having different thicknesses across the layer and without using an extra mask, or with only one extra mask. The total number of masks may be low compared to conventional manufacturing processes.

In a display 200 as shown in FIG. 3, the tuning layer 312 may have a different thickness for each sub-pixel. For example, the tuning layer 312 may be formed from, or otherwise include, ITO. Each tuning layer may include two ITO layers, ITO-1 and ITO-2.

Conventionally, a first ITO layer has the same thickness for all the sub-pixels, while a second ITO layer has different thicknesses for different sub-pixels such that each tuning layer 312 has a different thickness for the respective sub-pixel. The tuning layer is deposited with an additional mask, which is different from the mask for depositing the first ITO layer. After the first ITO layer (ITO-1) is deposited as a base layer, the tuning layer 312 may be deposited over the first ITO layer. The tuning layer including the first and second ITO layers. The second ITO layer (ITO-2) 312 may be thicker than the first ITO-1, and is deposited in a subsequent stage. Generally, after depositing an ITO layer, an etching step is followed to remove a portion of the ITO to form pixel electrodes or patterned anodes, such that each pixel or sub-pixel has an anode or pixel electrode to control the current through the OLED. Etching may be performed by using a solution or a solvent that dissolves the ITO. Because the etching step does not differentiate between the two different ITO layers, an additional photoresist layer may be deposited between the two ITO layers to protect the underlying ITO. For example, a first photoresist layer may be deposited around the ITO-1 layer to protect the ITO-1 during etching for a first sub-pixel while depositing ITO-2 for the second and third sub-pixels, which requires a first mask. Next, the ITO-2 layer is deposited over the ITO-1 layer to form ITO-2 for the second and third sub-pixels, which requires a second mask. Following this, the ITO-1 and ITO-2 layers of the second sub-pixel are protected by a second photoresist layer such that only the ITO-2 for the third sub-pixel is exposed. This photoresist deposition may require a third mask and is followed by deposition of the ITO-3 over the exposed ITO-2 for the third sub-pixel, which requires a fourth mask. Overall, this conventional process is complicated and may require up to four extra masks, as described above.

The present disclosure provides a method that uses a shadow mask instead of the extra four masks that are commonly used. The shadow mask is used for deposition of the OLED emitter 220. The shadow mask is also used to deposit the tuning layer 312 in the sub-pixel region 220 or OLED aperture area. The tuning layer 312 has different thicknesses for different sub-pixels. Each sub-pixel may be formed with a different shadow mask. For example, there are three shadow masks for red, green, and blue sub-pixels.

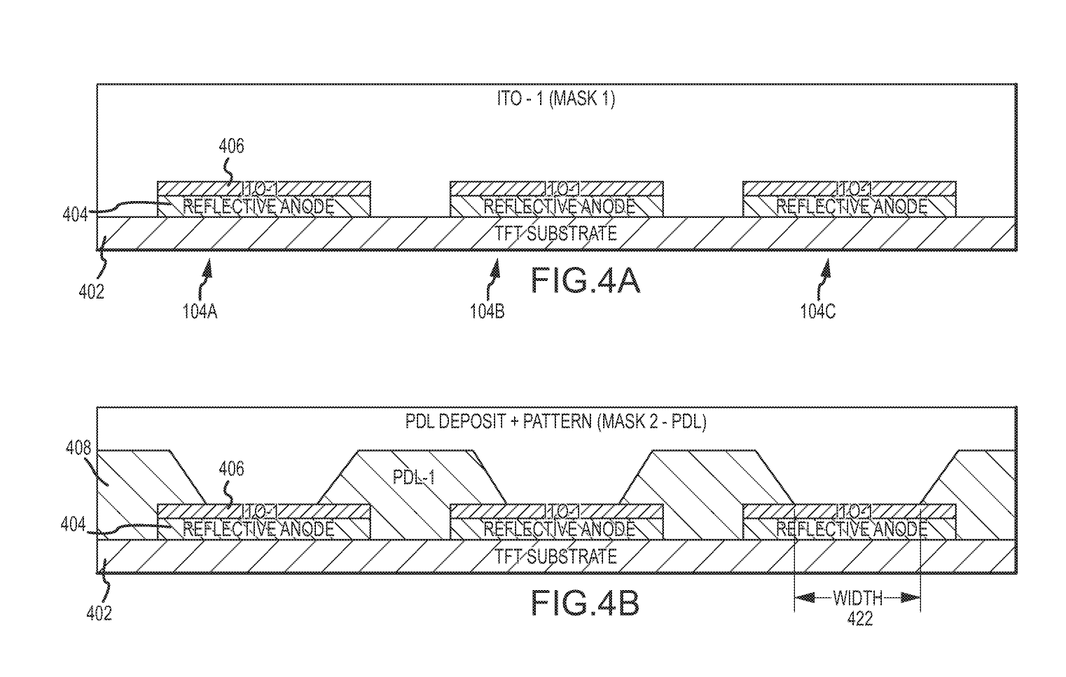

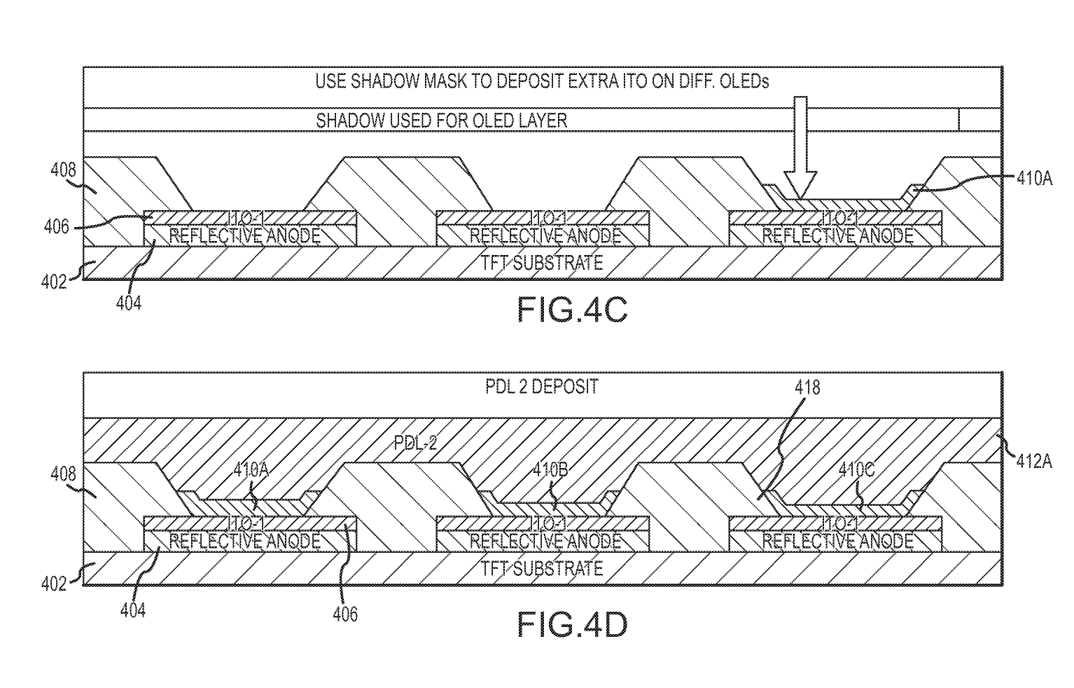

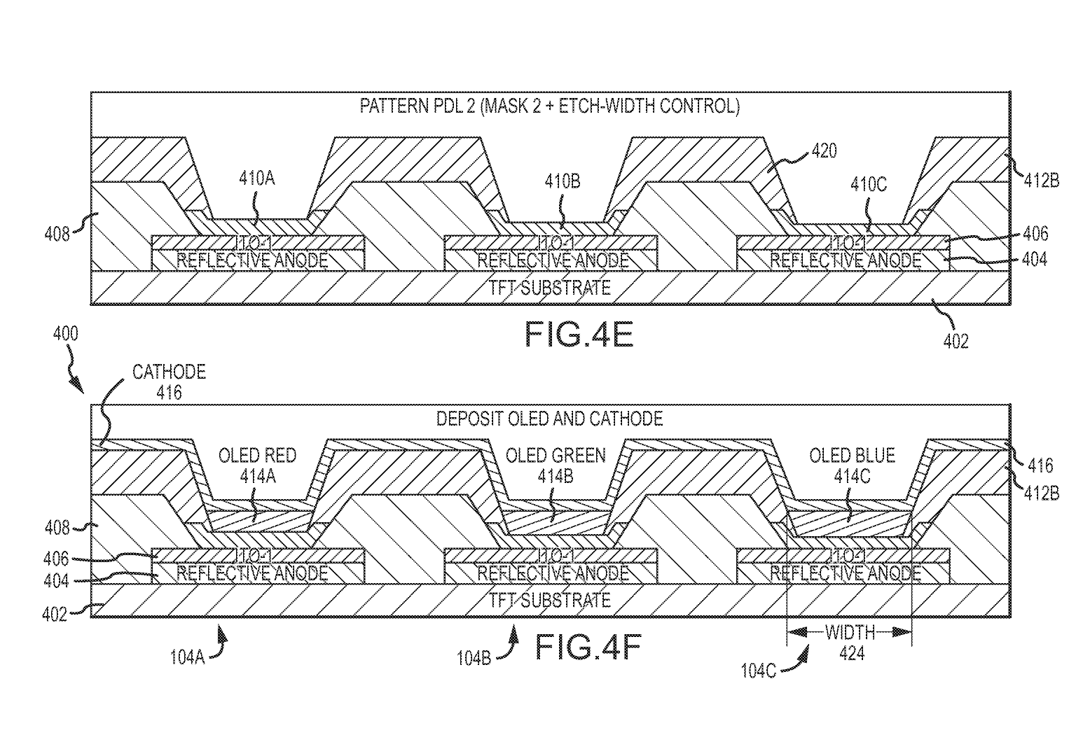

FIG. 4A shows a cross-sectional view of a process architecture, including anode and ITO photo patterning, for a top emission OLED display in one embodiment of the present disclosure. As shown, a reflective anode 404 is first deposited over a TFT substrate 402. Then, a first ITO layer (ITO-1) 406 is deposited over the reflective anode and patterned by using a first mask. The first ITO layer may be formed by a sputtering process. Each of the sub-pixels 104A, 104B, and 104C has substantially identical reflective anodes 404 and ITO-1 layers 406.

FIG. 4B shows a cross-sectional view of the process architecture, including pixel defining layer (PDL) deposition and photo patterning, for the top emission OLED display following the operation of FIG. 4A. As shown, the first PDL layer (PDL-1) 408 is deposited and patterned by using a second mask, such that the PDL-1 408 covers end portions of the ITO-1 406 and exposes the middle portion of the ITO-1.

Specifically, a photoresist layer is formed over the first PDL-1 by using a second mask. Depending upon the type of photoresist, either developed photoresist or unexposed photoresist may be removed by wet etching to expose the ITO-1 in the OLED aperture region. Generally, a photoresist film may be made of a photosensitive material, which exposes to light (or particular wavelengths of light) to develop the photoresist. The developed photoresist may be insoluble or soluble to a developer. There may be two types of photoresist, a positive photoresist and a negative photoresist. The positive photoresist is soluble to the photoresist developer. The portion of the positive photoresist that is unexposed remains insoluble to the photoresist developer. The negative resist is a type of photoresist in which the portion of the photoresist that is exposed to light becomes insoluble to the photoresist developer. The unexposed portion of the photoresist is dissolved by the photoresist developer.

In one embodiment, a positive photoresist is first deposited on a surface, and then light is selectively passed through a patterned photo mask that may block light in certain areas. The unexposed photoresist film is developed through the patterned photo mask to form the photoresist patterns as shown. In other words, the photoresist has the same pattern as the photo mask. The unexposed photoresist film protects the layers underneath during an etching process, such that the portion exposed by the photoresist may be completely removed by the etching process, such as a wet etching. Portions of underlying layers that are protected by photoresist generally are not removed or otherwise etched. After etching to form a pattern of a deposited layer by using photoresist, the insoluble photoresist is removed prior to the next deposition operation. Different masks may be provided to form various films with different patterns. In alternative embodiments, different photoresist may be used. It will be appreciated by those skilled in the art that the photo mask will vary with the negative photoresist.

FIG. 4C shows a cross-sectional view of the process architecture, including tuning layer deposition by using a shadow mask, for the top emission OLED display following the operation of FIG. 4B. After the first pixel-defining layer patterning, a second ITO layer 410A is deposited over the ITO-1 406 for the sub-pixel 104C in the OLED aperture area 230 by using the shadow mask as used for depositing OLED 414A. The second ITO layer is the tuning layer. The tuning layer in the OLED aperture area may be deposited by a vacuum process, such as a sputtering process. The end portions of ITO-2 406 (e.g., the tuning layer) adhere to the sides 418 of the first PDL layer or PDL-1 408.

FIG. 4D shows a cross-sectional view of the process architecture, including a deposited second pixel defining layer (PDL), for the top emission OLED display and following the operation of FIG. 4C. By using the shadow masks that are used for depositing OLEDs 414B and 414C to repeat deposition of ITO-2 in the first and second sub-pixel regions, different thicknesses of the ITO-2 are formed for the sub-pixels. As shown, the thickness of the ITO-2 or tuning layer 410A is thicker than ITO-2 410B, which is thicker than ITO-2 410C. If OLED emitter 220 and cathode 202 are directly deposited on top of the anode 202, there may be a short between the anode and cathode. Therefore, a second pixel-defining layer (PDL-2) 412A may be deposited over the ITO-2 410A, 410B and 410C and the PDL-1 408 to prevent shorting between the anode and the cathode.

FIG. 4E shows a cross-sectional view of the process architecture, including photo patterning of the second PDL for the top emission OLED display, and following the operation of FIG. 4D. The PDL-2 412A is patterned to form PDL-2 412B, such that the PDL-2 covers the end portions of the second ITO layers 410A, 410B, and 410C. The PDL-2 410A may be patterned using the same mask (i.e. mask 2) as the first pixel defining layer (PDL-1). The PDL-2 410A may be etched to form PDL-2 412B such that the width 424 of the etched portions of the PDL-2 is controlled to ensure that the tuning layer (410A, 410B, 410C) is electrically isolated from the cathode 416. Note that the width 424 of the OLED aperture is slightly smaller than the width 422 of the OLED aperture after the operation in FIG. 4B, due to the deposition of the tuning layer 410.

FIG. 4F shows a cross-sectional view of a process architecture, including light emitting layer deposition and common electrode deposition, for the top emission OLED display and following the operation of FIG. 4E. After forming the ITO-2 layer with different thicknesses at different sub-pixel regions of the layer, the OLED emitters 414A, 414B, and 414C are formed over the ITO-2. This is followed by depositing cathode 416 over the sub-pixels and the PDL-2 412B.

In an alternative embodiment, an additional mask may be used to help accurate control of PDL-2 layer. The etching process for PDL-2 is the same as that of PDL-1 After patterning the PDL-2, the OLED layers may be deposited over the tuning layer, and then a common electrode or cathode layer is deposited over the OLED layers and the PDL-2 layer.

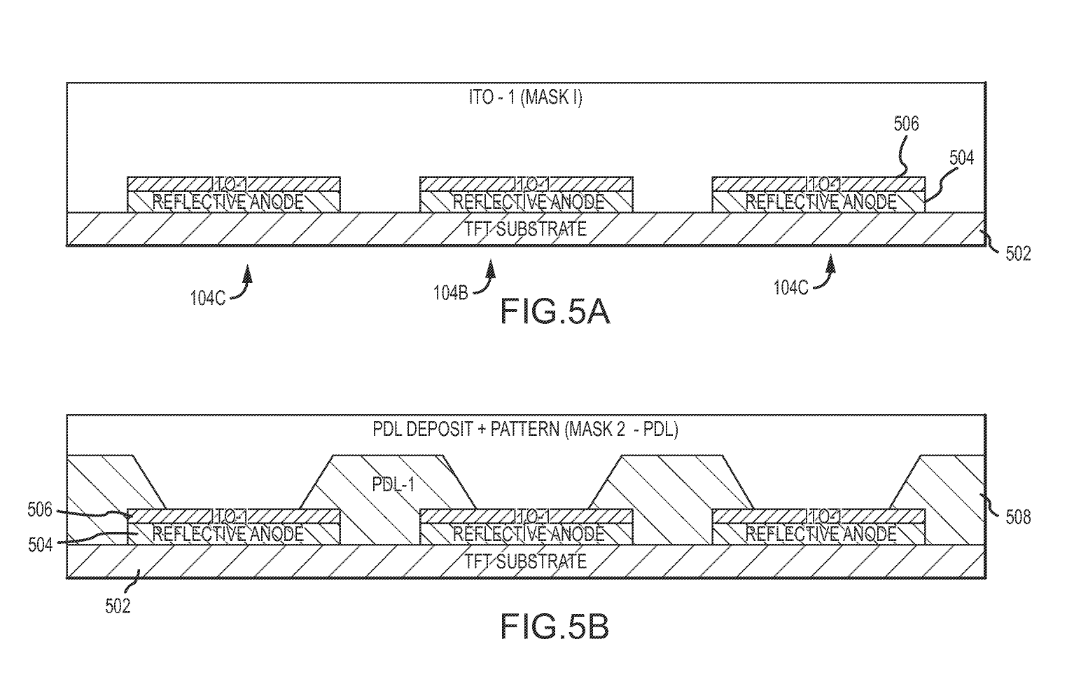

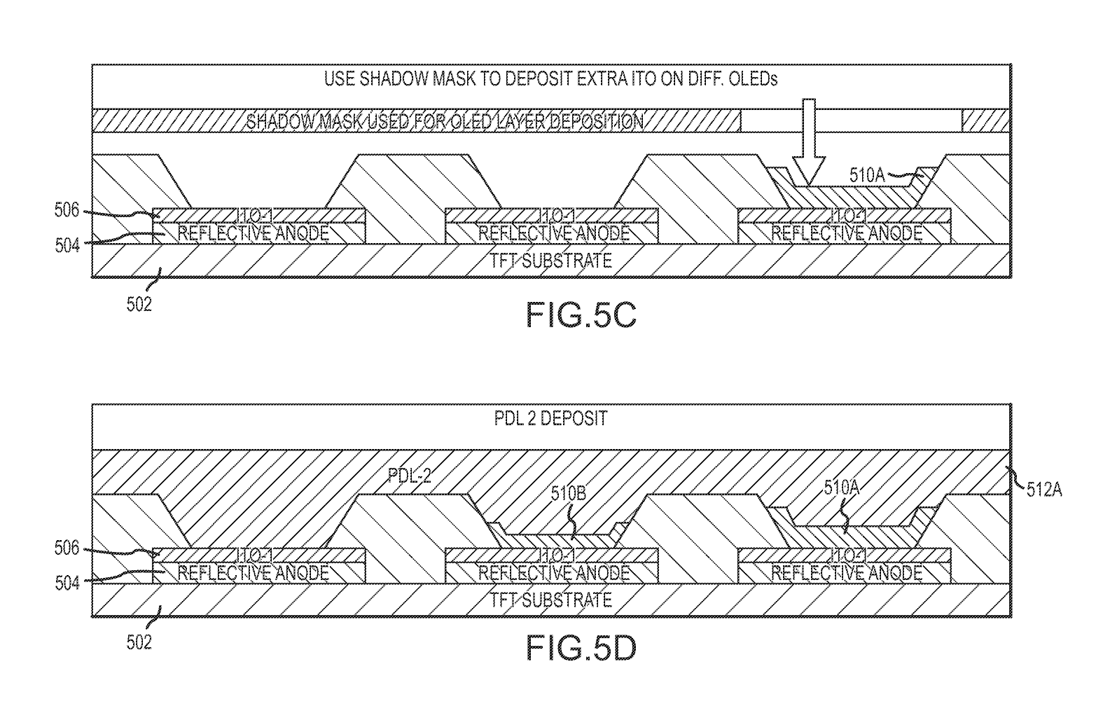

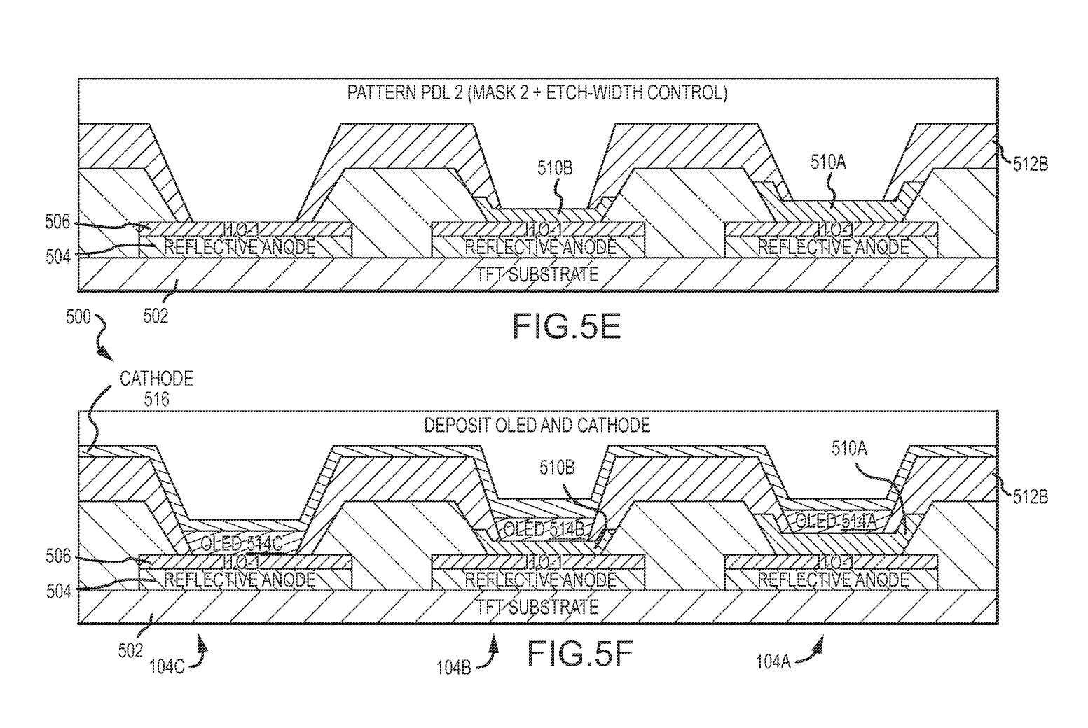

A second embodiment of the present disclosure shows that only two more tuning films are deposited to make three different thicknesses of the tuning layers for the Red, Green, and Blue sub-pixels. FIG. 5A shows a cross-sectional view of a process architecture, including anode and ITO photo patterning, for a top emission OLED display in accordance with a second embodiment of the present disclosure. FIG. 5B shows a cross-sectional view of the process architecture, including pixel defining layer (PDL) deposition and photo patterning for the top emission OLED display, following the operation of FIG. 5A. A reflective anode 504 is first deposited over a TFT substrate 502. Then, a first ITO layer (ITO-1) 506 is deposited over the reflective anode and patterned by using a first mask. A first PDL layer (PDL-1) 508 is deposited and patterned by using a second mask, such that the PDL-1 508 covers end portions of the ITO-1 506 and exposes the middle portion of the ITO-1.

FIG. 5C shows a cross-sectional view of the process architecture, including tuning layer deposition by using a shadow mask, for a top emission OLED display and following the operation of FIG. 5B. As shown, a second ITO layer 510A is deposited over the ITO-1 506 for the sub-pixel 104A (red sub-pixel) in the OLED aperture area 240 by sputtering, using the shadow mask previously used to deposit the reflective anode 504. The tuning layer 510A in FIG. 5C is thicker than the tuning layer 410C in FIG. 4C. The different thicknesses in the tuning layer generally results in different optical path lengths for the sub-pixels.

FIG. 5D shows a cross-sectional view of the process architecture, including second pixel defining layer (PDL) deposition for the top emission OLED display, following the operation of FIG. 5C. As shown, the first sub-pixel 104A does not have any tuning layer, while the second sub-pixel 104B has a thinner tuning layer than the third sub-pixel 104C. This varying thickness of the tuning layers 510A and 510B for the sub-pixels may be formed by using the same shadow mask to cover some of the sub-pixel regions while depositing the tuning layer in other sub-pixel regions.

FIG. 5E shows a cross-sectional view of the process architecture, including photo patterning of the second PDL for the top emission OLED display, following the operation of FIG. 5D. FIG. 5F shows a cross-sectional view of a process architecture, including light emitting layer deposition and common electrode deposition for the top emission OLED, display following the operation of FIG. 5E. Note that FIGS. 5E-5F are similar to FIGS. 4E-4F, but there is no tuning layer for sub-pixel 104C.

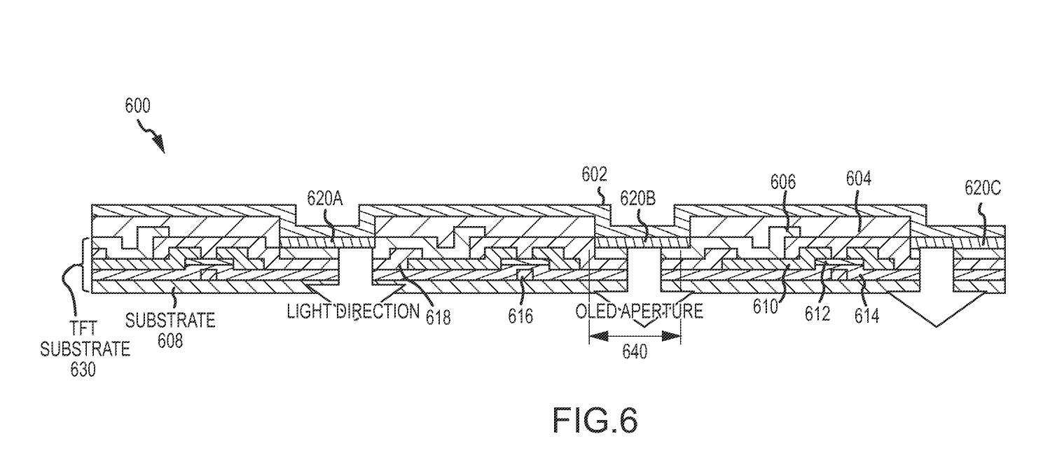

FIG. 6 illustrates a cross-sectional view of a bottom emission OLED in accordance with certain embodiments in accordance with certain embodiments of the present disclosure. As shown, bottom emission OLED display 600 has OLED EMLs 620A, 620B and 620C for emitting red light, green light and blue light, respectively. The OLED aperture 640 is smaller than the OLED aperture 240, as shown in FIG. 2, for the top emission OLED 200. Here, light is emitted from the bottom of the OLED display 600, as indicated by the arrows shown on FIG. 6. Accordingly, t substrate 608 may be substantially transparent. For each of the sub-pixels 104A, 104B, and 104B (emitting red light, green light, and blue light, respectively), the corresponding OLED EMLs 620A, 620B, and 620C have different thicknesses such that a variable optical path length is achieved for the sub-pixels. In other words, the optical path length varies between sub-pixels.

The bottom emission OLED display 600 includes a TFT substrate 630 which includes gate electrodes 616, and source and drain electrode 610 separated from the gate electrodes by a gate insulator 614. The TFT 630 also include a channel 612 and a passivation (PV) layer over the channel and source and drain electrodes. The bottom emission OLED display 600 also includes an anode 606 for each sub-pixel, a cathode 602 for all sub-pixels separated from the anode by a pixel defining layer 604. It will be appreciated by those skilled in the art that the variable optical path length may be achieved by using the shadow mask for the bottom emission OLED.

The present disclosure provides methods with several benefits over of the conventional technology. The benefits include reducing the number of mask numbers and increasing product throughput at lower production cost.

Having described several embodiments, it will be recognized by those skilled in the art that various modifications, alternative constructions, and equivalents may be used without departing from the spirit of the disclosure. Additionally, a number of well-known processes and elements have not been described in order to avoid unnecessarily obscuring the embodiments disclosed herein. Accordingly, the above description should not be taken as limiting the scope of the document.

Those skilled in the art will appreciate that the presently disclosed embodiments teach by way of example and not by limitation. Therefore, the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. An organic light emitting diode display comprising:
a plurality of pixels on a substrate, each pixel comprising at least three sub-pixels, each sub-pixel emitting light of different wavelengths from each other;
thin film transistors (TFTs) for the at least three sub-pixels on the substrate, each of the at least two TFTs being separated from each other by a first pixel defining layer;
a pixel electrode connected to the TFT for each sub-pixel;
a tuning layer on the first pixel electrode, wherein the tuning layer has a thickness for each sub-pixel such that each sub-pixel has an optical-path length different from another sub-pixel;
an organic light emitting layer disposed over the tuning layer;
a second pixel defining layer covering a first end of the tuning layer and a second end of the tuning layer opposing to the first end of the tuning layer, and exposing the light emitting layer; and
a common electrode disposed over the second pixel defining layer and the light emitting layer for the plurality of the pixels and the at least three sub-pixels, wherein a microcavity is formed between the first pixel electrode and the second pixel electrode for each sub-pixel.

2. The organic emitting diode display of claim 1, wherein the first pixel electrode comprises a light reflector coupled to a substrate, wherein the tuning layer is between the light reflector and the light emitting layer.

3. The organic emitting diode display of claim 2, wherein the light reflector comprises silver (Ag).

4. The organic emitting diode display of claim 1, wherein the common electrode comprises a conductive layer.

5. The organic emitting diode display of claim 4, wherein the conductive material comprises indium-tin-oxide (ITO).

6. The organic emitting diode display of claim 4, wherein the conductive layer comprises silver (Ag).

7. The organic emitting diode display of claim 1, wherein the tuning layer comprises indium-tin-oxide (ITO).

8. The organic emitting diode display of claim 1, wherein the light emitting layer comprises an organic light emitting material.

9. The organic emitting diode display of claim 1, wherein the first and second pixel defining layers comprise an organic material.

10. A method of fabricating a top emission organic light emitting diode (OLED) display having a plurality of pixels, each pixel having at least three sub-pixels, the method comprising:
forming a plurality of first pixel electrodes for the sub-pixels over a thin film transistor (TFT) substrate such that the first pixel electrode for one sub-pixel is separated from another sub-pixel by a first pixel defining layer;
disposing an tuning layer over the first pixel electrode by using a shadow mask, the tuning layer having a different thickness for each sub-pixel that emits light of a different wavelength, the shadow mask being different for each sub-pixel;
depositing a second pixel defining layer over the tuning layer;
removing a first portion of the second pixel defining layer such that a middle portion of the tuning layer is exposed and an end portion remains covered by a remaining second portion of the second pixel defining layer;
disposing a light emitting layer over the middle portion of the tuning layer by using the shadow mask; and
forming a common electrode over the light emitting layer and the remaining second portion of the second pixel defining layer for the plurality of pixels and the at least three sub-pixels.

11. The method of claim 10, wherein the first pixel electrode comprises a light reflector and a transparent conductive layer.

12. The method of claim 11, wherein the transparent conductive layer comprises indium-tin-oxide (ITO).

13. The method of claim 10, wherein the common electrode comprises a conductive layer.

14. The method of claim 13, wherein the transparent conductive layer comprises indium-tin-oxide (ITO).

15. The method of claim 13, wherein the conductive layer comprises silver.

16. The method of claim 10, wherein the tuning layer comprises indium-tin-oxide (ITO).

17. The method of claim 10, wherein the light emitting layer comprises an organic light emitting material.

18. The method of claim 10, wherein the first and second pixel defining layers comprise an organic material or an inorganic material.

19. An organic light emitting diode display comprising:
a plurality of pixels on a substrate, each pixel comprising three sub-pixels, each sub-pixel emitting light of different wavelengths from each other;
thin film transistors (TFTs) for the sub-pixels on the substrate, each TFT being separated from each other by a first pixel defining layer;
a pixel electrode connected to the TFT for each sub-pixel;
a tuning layer on the first pixel electrode, wherein the tuning layer has a thickness for each sub-pixel such that each sub-pixel has an optical-path length different from another sub-pixel;
an organic light emitting layer disposed over the tuning layer; and
a second pixel defining layer covering a first end of the tuning layer and a second end of the tuning layer opposing to the first end of the tuning layer, and exposing the light emitting layer.
